(19) United States
(12) Patent Application Publication
(10) Pub. No.: US 2010/0172110 A1
(43) Pub. Date: Jul. 8, 2010

(54) ELECTRONIC APPARATUS

(75) Inventors: Yoshiro Tanaka, Kawasaki (JP); Goro Nakagai, Kawasaki (JP); Kaigo Tanaka, Kawasaki (JP)

Correspondence Address: KRATZ, QUINTOS & HANSON, LLP, 1420 K Street, N.W., 4th Floor, WASHINGTON, DC, 20005, US

(73) Assignee: FUJITSU LIMITED, Kawasaki (JP)

(21) Appl. No.: 12/649,522

(22) Filed: Dec. 30, 2009

(30) Foreign Application Priority Data
Jan. 6, 2009 (JP) 2009-1086

(51) Int. Cl. H05K 1/18

(52) U.S. Cl. 361/748

(57) ABSTRACT

An electronic apparatus includes a printed board having a mounting surface and a ground layer, a peripheral circuit of a memory, which is mounted in the electronic apparatus, being mounted on the mounting surface, a metal plate disposed above the mounting surface, and a plurality of conductive portions that electrically connect the ground layer and the metal plate to each other, wherein the peripheral circuit is mounted between the conductive portions.

### CROSS-REFERENCE TO RELATED APPLICATIONS

This application is based upon and claims the benefit of priority of Japanese Patent Application No. 2009-1086, filed on Jan. 6, 2009, the entire contents of which are incorporated herein by reference.

### FIELD

The embodiments discussed herein are related to an electronic apparatus.

### BACKGROUND

In recent years, countermeasures against electromagnetic interference (EMI) have been taken in electronic apparatuses such as desktop personal computers, notebook personal computers, and printers, which are information technology equipment. Each country has individualized regulations regarding electromagnetic compatibility (EMC). Manufacturers of information technology equipment cannot sell or ship products to any country unless the products comply with standards regarding the EMC regulation in that country. Examples of standards regarding the EMC regulation include the codes and rules of the Voluntary Control Council for Interference (VCCI) in Japan, the rules of the Federal Communications Commission (FCC) in the United States, and the international CISPR standards established by the Comité International Spécial des Perturbations Radioélectriques (International Special Committee on Radio Interference) (CISPR). Many countries adopt standards which are basically compatible with the CISPR standards. If the CISPR standards can be satisfied, the EMC regulations in individual countries can basically be satisfied.

Therefore, countermeasures against EMI (or countermeasures against electromagnetic noise) are implemented in many electronic apparatuses. Some of these electronic apparatuses include a printed board on which a slot member for receiving a memory is mounted. In general, a wiring pattern for a memory transmits high-speed signals. Such a signal generates high-level electromagnetic noise, and therefore it is difficult to take a countermeasure against the EMI caused by the memory.

Please refer to Japanese Laid-open Patent Publication No. 2009-141057.

### SUMMARY

According to an embodiment, an electronic apparatus includes a printed board having a mounting surface and a ground layer, a peripheral circuit of a memory, which is mounted in the electronic apparatus, being mounted on the mounting surface, a metal plate disposed above the mounting surface, and a plurality of conductive portions configured to electrically connect the ground layer and the metal plate to each other, wherein the peripheral circuit is mounted between the conductive portions.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1 is a perspective view of a notebook personal computer;

FIG. 2 is a diagram illustrating the bottom side of a main body;

FIG. 3 is a diagram illustrating the inner structure of the main body;

FIG. 4 is a diagram illustrating the top side of the main body;

FIG. 5 is a diagram illustrating the top side of the main body in a state in which a keyboard is removed;

FIG. 6 is a diagram illustrating the structure of a printed board;

FIGS. 7A to 7C are diagrams illustrating modifications;

FIG. 8 is a diagram illustrating the effect of reducing noise in accordance with the number and positions of connecting sections; and

FIG. 9 is a table illustrating the results of an experiment.

### DETAILED DESCRIPTION OF EMBODIMENTS

An example of a printed board includes two ground layers, a signal layer disposed between the two ground layers, and a power layer disposed between the two ground layers. A wiring pattern for a memory is provided on the signal layer disposed between the two ground layers. Since the wiring pattern for the memory is interposed between the two ground layers, the electromagnetic noise caused by the memory can be reduced.

However, recently, printed boards having only one ground layer have been used for the purpose of reducing costs. Unlike the printed board having two ground layers, in a printed board having only one ground layer, it is not possible to interpose the wiring pattern between two ground layers. Therefore, in the printed board having only one ground layer, there is a possibility that the noise caused by the memory will increase.

An electronic apparatus disclosed in this specification includes a metal plate, a printed board, and a plurality of conductive portions. The printed board includes a mounting surface on which a component of a peripheral circuit of a memory, which is mounted in the electronic apparatus, is mounted and a ground layer disposed such that the mounting surface is interposed between the metal plate and the ground layer. The conductive portions electrically connect the ground layer and the metal plate to each other. An imaginary line which interconnects connecting sections between the metal plate and the conductive portions crosses at least a part of a mounting area in which the component is mounted on the mounting surface.

The ground layer included in the printed board and the metal plate are electrically connected to each other; and the peripheral circuit is interposed between the ground layer included in the printed board and the metal plate. Therefore, the electromagnetic noise emitted from the peripheral circuit can be reduced. In addition, since the imaginary line which interconnects the connecting sections between the metal plate and the conductive portions crosses at least a part of the mounting area, the electromagnetic noise emitted from the peripheral circuit can be further reduced. Thus, the noise caused by the memory can be reduced.

An electronic apparatus disclosed in this specification includes a metal plate, a printed board, and a plurality of conductive portions. The printed board includes a slot member for a memory, a first surface which faces the metal plate and on which a component of a peripheral circuit of the memory is mounted, a second surface on which the slot member is mounted, and a ground layer. The conductive portions electrically connect the ground layer and the metal plate to each other. A plurality of imaginary lines which interconnect connecting sections between the metal plate and the conductive portions surround at least a part of a mounting area in which the component of the peripheral circuit is mounted.

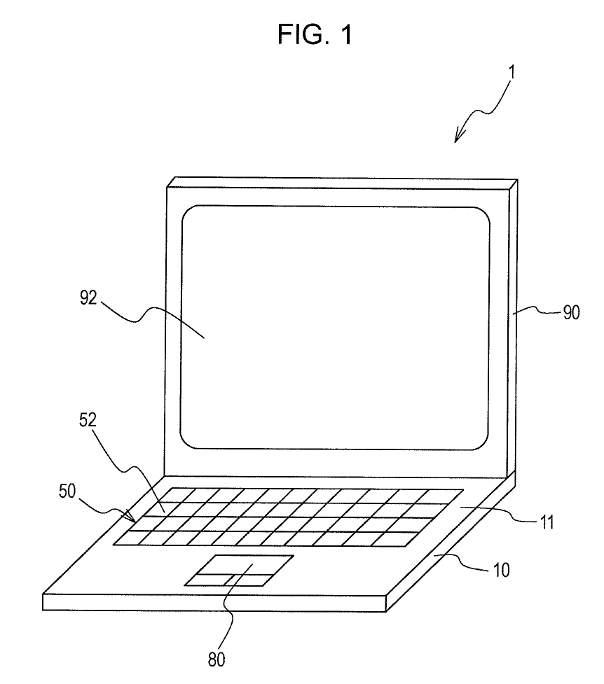

FIG. 1 is a perspective view of a notebook personal computer 1. The notebook personal computer 1 includes a main body 10 and a display unit 90. The notebook personal computer 1 is an example of an electronic apparatus. The main body 10 and the display unit 90 are connected to each other in a pivotable manner. A keyboard 50 and a pointing device 80 are provided on a top surface 11 of the main body 10. The display unit 90 is provided with a display 92. The keyboard 50 includes a plurality of input keys 52. A desired image is displayed on the display 92 in response to an input operation of the keyboard 50 and the pointing device 80.

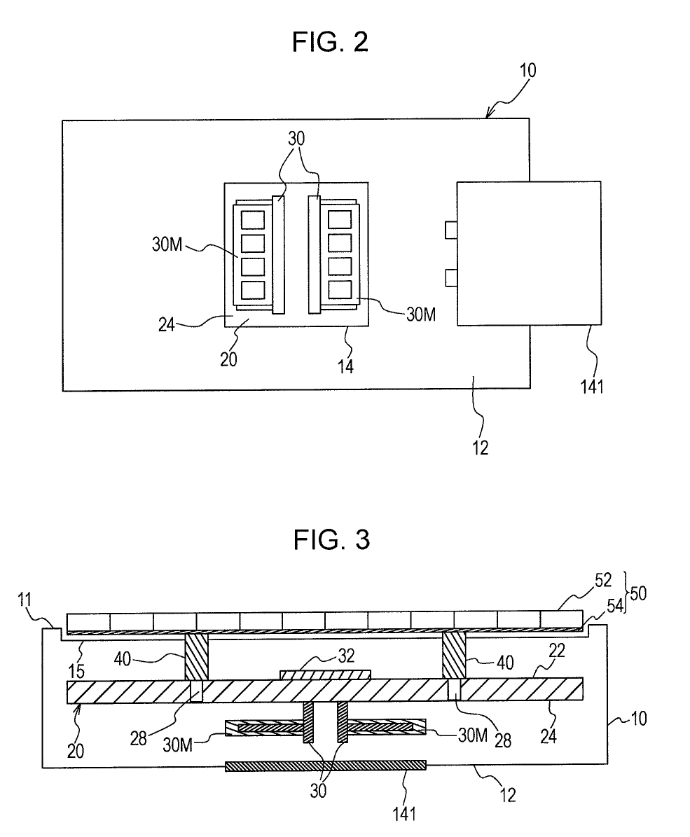

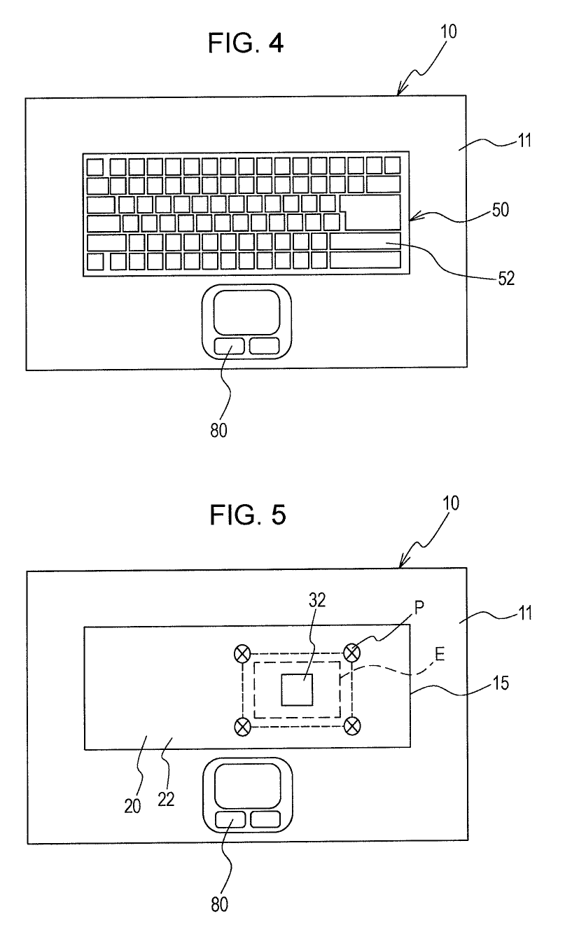

FIG. 2 is a diagram illustrating a bottom surface 12 of the main body 10. FIG. 3 is a diagram illustrating the inner structure of the main body 10. FIG. 4 is a diagram illustrating the top surface 11 of the main body 10. As shown in FIG. 2, an opening 14 is formed in the bottom surface 12 of the main body 10, and a cover 141 which covers the opening 14 is provided on the bottom surface 12 of the main body 10. Slot members 30 are mounted on a bottom surface 24 of a printed board 20. Memories 30M are attached to the slot members 30. The memories 30M can be attached to or detached from the slot members 30 through the opening 14 while the cover 141 is removed.

As shown in FIG. 3, the printed board 20 and the slot members 30 are housed in the main body 10. Electronic components, such as a central processing unit (CPU), are mounted on the printed board 20. The printed board 20 corresponds to a mother board. An electronic component 32 is mounted on a top surface 22 of the printed board 20. The electronic component 32 is electrically connected to the slot members 30. The electronic component 32 corresponds to a peripheral circuit of the memories 30M attached to the slot members 30. The electronic component 32 is mounted on a surface layer at a side opposite to the side at which the slot members 30 are mounted. The top surface 22 of the printed board 20 corresponds to a first surface, and the bottom surface 24 thereof corresponds to a second surface. The top surface 22 corresponds to a mounting surface on which a component of a peripheral circuit of a memory, which is mounted in the electronic apparatus, is mounted. The electronic component 32 on the top surface 22 of the printed board 20 includes other electronic components for the memories 30M and a wiring pattern.

As shown in FIG. 3, the keyboard 50 includes the input keys 52 and a support plate 54 which supports the input keys 52. The support plate 54 is made of metal. A recessed portion 15 which defines the position at which the keyboard 50 is mounted is provided at the top surface 11 of the main body 10. The support plate 54 corresponds to a metal plate.

The printed board 20 is provided with signal grounds 28 which are electrically connected to a ground layer G included in the printed board 20. The signal grounds 28 are electrically connected to the support plate 54 by conductive members 40. The conductive members 40 shown in FIG. 3 have a cylindrical shape. Since the conductive members 40 have a cylindrical shape, connecting sections between the support plate 54 and the conductive members 40 are directly above the signal grounds 28. However, the shape of the conductive members 40 is not limited to the above-described shape. For example, in the case where the connecting sections between the support plate 54 and the conductive members 40 are to be located at positions other than directly above the signal grounds 28, conductive members having an L shape in a side sectional view may also be used. In addition, the conductive members 40 may be spring-shaped members, plate-shaped members, conductive gaskets, fingers, pieces of conductive tape, etc., or any combination thereof. The conductive tape may be, for example, copper tape, aluminum tape, or conductive cloth.

FIG. 5 is a diagram illustrating the top surface 11 of the main body 10 in a state in which the keyboard 50 is removed. FIG. 5 shows connecting sections P between the support plate 54 and the conductive members 40. As shown in FIG. 5, four connecting sections P are provided. The connecting sections P are positioned such that imaginary lines which interconnect the connecting sections P positioned next to each other surround a mounting area E. The mounting area E is an area in which a component of a peripheral circuit of the memories 30M is disposed. The peripheral circuit includes electronic components and a wiring pattern. The electronic components include termination resistances, bypass capacitors, or the like. The wiring pattern includes memory data lines and power source patterns for the memories 30M. The mounting area E is provided on the top surface 22 of the printed board 20 which faces the support plate 54.

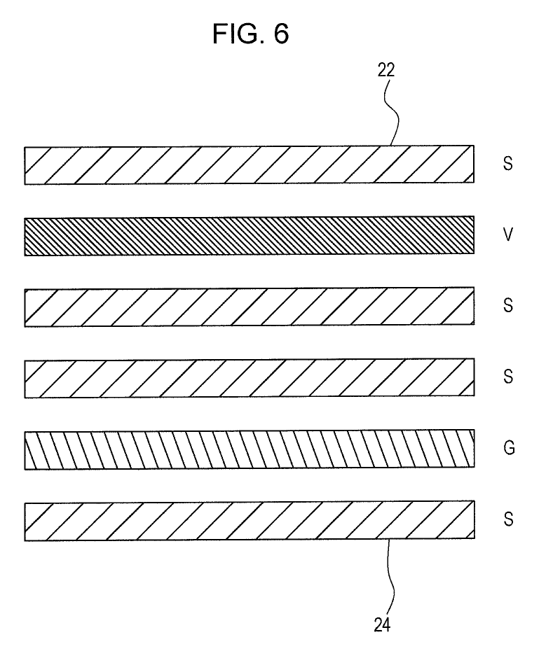

FIG. 6 is a diagram illustrating the structure of the printed board 20. The printed board 20 includes a signal layer S, a power layer V, a signal layer S, a signal layer S, a ground layer G, and a signal layer S in that order from the top surface 22 to the bottom surface 24. Thus, the printed board 20 has a six-layer structure.

Main portions of the wiring pattern for the slot members 30 and the memories 30M are provided in the inner signal layers S interposed between the power layer V and the ground layer G. Substantially no wiring pattern for the slot members 30 is provided on the signal layers S on the surfaces of the printed board 20 at the outermost positions thereof. The wiring pattern for the slot members 30 and the memories 30M transmit high-speed signals. Therefore, the electromagnetic noise emitted from the printed board 20 can be reduced by the above-described structure.

As shown in FIG. 3, the signal grounds 28 provided in the printed board 20 are electrically connected to the support plate 54. Therefore, the electronic component 32 and the mounting area E are surrounded by the ground layer G in the printed board 20 and the support plate 54. With this structure, the ground layer G included in the printed board 20 and the support plate 54 function as shields for blocking the noise caused by the memories 30M; and therefore, the noise emitted from the mounting area E can be reduced.

In addition, since the connecting sections P are positioned such that the connecting sections P surround the mounting area E as shown in FIG. 5, the noise caused by the memories 30M can be reduced.

According to the present embodiment, the noise can be reduced even if there is only one ground layer. In the case where the number of the ground layer is one, the manufacturing cost of the printed board can be reduced.

In the present embodiment, the ground layer G included in the printed board 20 and the support plate 54 are electrically connected to each other by the conductive members 40. Therefore, the manufacturing cost and the noise can be reduced.

The distance between the connecting sections P which are closest to each other is preferably about one-fourth of a wavelength of an electromagnetic wave with a predetermined frequency. For example, first, the wavelength of the electromagnetic noise emitted from an area around the mounting area E in the case where the conductive members 40 are not provided can be measured. As a result of the measurement, the frequency of the electromagnetic noise to be reduced can be determined as, for example, 1,000 MHz. In this case, the wavelength of the electromagnetic wave with a frequency of 1,000 MHz is about 30 cm; and the distance corresponding to one-fourth of the wavelength is about 7.5 cm. Therefore, the distance between the connecting sections P which are closest to each other can be set to about 7.5 cm or less. Thus, the emission of the electromagnetic noise with a frequency of 1,000 MHz can be reduced.

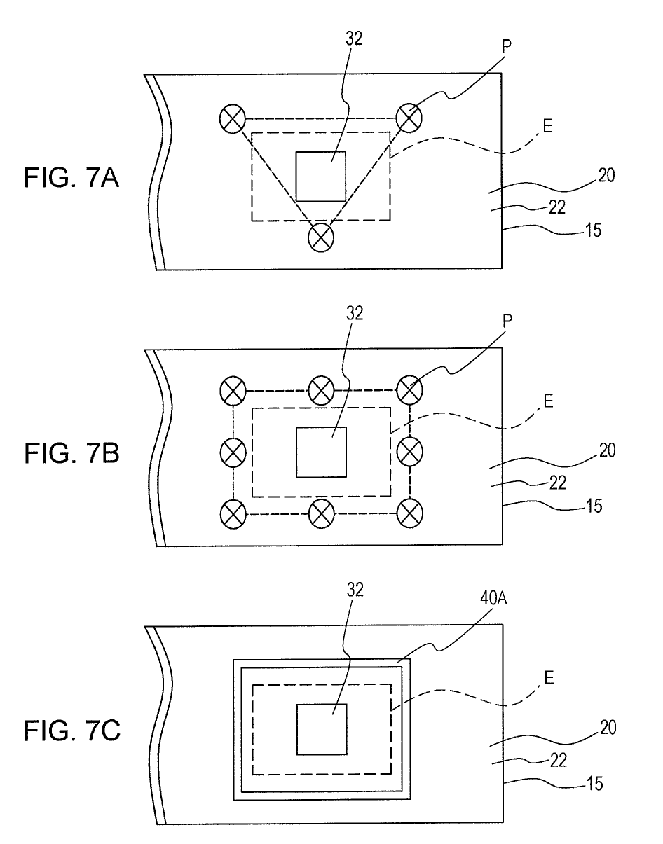

A first modification will now be described. FIG. 7A is a diagram illustrating the first modification. As shown in FIG. 7A, three connecting sections P are provided in the first modification. Imaginary lines which interconnect the connecting sections P surround a portion of the mounting area E. Also in this case, the noise can be reduced.

FIG. 7B is a diagram illustrating a second modification. As shown in FIG. 7B, eight connecting sections P may be provided such that the connecting sections P surround the mounting area E. Since the distances between the connecting sections P positioned next to each other can be reduced, the emission of harmonic waves can also be reduced.

FIG. 7C is a diagram illustrating a third modification. As shown in FIG. 7C, a frame-shaped conductive member 40A may be provided. The conductive member 40A surrounds the mounting area E. Therefore, the emission of harmonic waves can also be reduced. The conductive member 40A is made of metal. The mounting area E is surrounded by the conductive member 40A, the ground layer G included in the printed board 20, and the support plate 54.

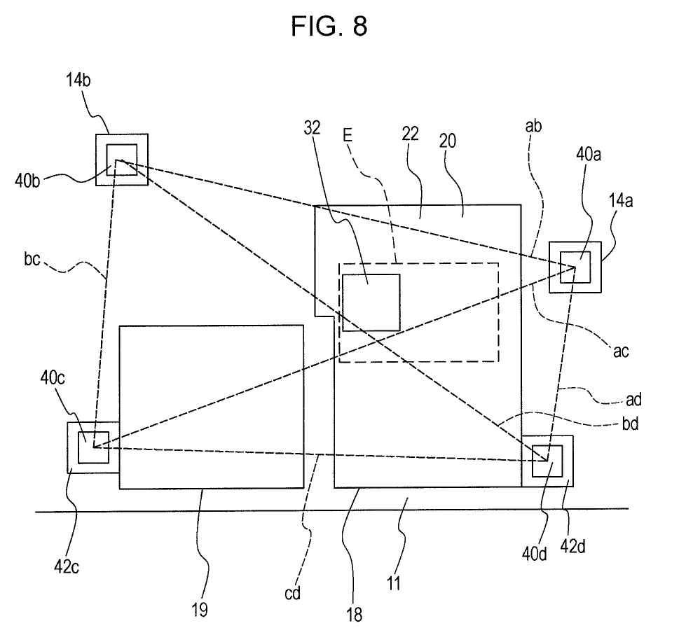

Variations in the effect of reducing the noise caused by the memories in accordance with the number and positions of the connecting sections will now be described. Comparative experiments for observing the variations in the effect of reducing the noise in accordance with the number and positions of the connecting sections have been carried out. FIG. 8 is a diagram illustrating the effect of reducing the noise in accordance with the number and positions of the connecting portions. FIG. 8 shows the top surface 11 in a state in which the keyboard 50 is removed. As shown in FIG. 8, the comparative experiments have been performed on the assumption that the maximum number of connecting sections is four.

FIG. 8 shows an imaginary line ab which interconnects conductive members 40a and 40b, an imaginary line be which interconnects conductive members 40b and 40c, an imaginary line cd which interconnects conductive members 40c and 40d, and an imaginary line ad which interconnects conductive members 40d and 40a. Similarly, FIG. 8 also shows an imaginary line ac which interconnects conductive members 40a and 40c and an imaginary line bd which interconnects conductive members 40b and 40d.

Openings 14a and 14b are formed in the top surface 11 to prevent interference with the conductive members 40a and 40b, respectively. A piece of aluminum tape 42c is attached to the top surface 11, and the conductive member 40c is placed on the aluminum tape 42c. The aluminum tape 42c is electrically connected to a finger (not shown) provided on the printed board 20. The finger is electrically connected to a signal ground provided in the printed board 20. Thus, the aluminum tape 42c is electrically connected to the ground layer in the printed board 20; and therefore, the conductive member 40c is electrically connected to the ground layer in the printed board 20. The conductive member 40d and a piece of aluminum tape 42d also have a similar structure.

Openings 18 and 19 are formed in the recessed portion 15. The recessed portion 15 is made of a material which is not conductive, so that the electronic components mounted on the top surface 22 of the printed board 20 and the support plate 54 of the keyboard 50 can be prevented from coming into contact with each other. The openings 18 and 19 are formed in the recessed portion 15 to ensure sufficient spaces for connecting the keyboard 50 and the pointing device 80 to the printed board 20 with flexible printed boards.

First, an experiment was performed while the connection was provided at two positions by the conductive members 40a and 40b. The imaginary line ab does not pass through the mounting area E or the electronic component 32. The field intensity of the interfering wave of the electromagnetic wave with a frequency in the range of about 30 MHz to about 1,000 MHz was measured while the connection is provided at two positions by the conductive members 40a and 40b. The field intensity of the interfering wave was measured for both a horizontally polarized wave and a vertically polarized wave. The comparative experiments were performed to compare the case in which the connection was provided at two positions by the conductive members 40a and 40b with the cases in which the connection was provided under other conditions described below. The above-described condition is hereinafter called a first condition.

Next, an experiment was performed while the connection was provided at two positions by the conductive members 40a and 40c. This condition is hereinafter called a second condition. The imaginary line ac passes through the mounting area E. It is noted that not only the electronic component 32 but also vias (not shown), resistors (not shown), etc., which are electrically connected to the slot members 30, are disposed in the mounting area E. The distance between the conductive members 40a and 40c is larger than 7.5 cm. The noise-reducing effect obtained under the second condition was larger than that obtained under the first condition by about 3 dB to 7 dB.

Next, an experiment was performed while the connection was provided at three positions by the conductive members 40a, 40b, and 40d. This condition is hereinafter called a third condition. A part of the electronic component 32 is surrounded by the imaginary lines ab, bd, and ad. However, the electronic component 32 is not entirely surrounded. Among the imaginary lines ab, bd, and ad, the imaginary line bd has the largest length and the imaginary line ad has the smallest length. The distance between the conductive members 40a and 40d is smaller than 7.5 cm. However, the distance between the conductive members 40b and 40d is larger than 7.5 cm. The noise-reducing effect obtained under the third condition was larger than that obtained under the first condition by about 1 dB to 7 dB.

Next, an experiment was performed while the connection was provided at three positions by the conductive members 40a, 40b, and 40c. This condition is hereinafter called a fourth condition. The electronic component 32 is entirely surrounded by the imaginary lines ab, bc, and ac. The noise-reducing effect obtained under the fourth condition was larger than that obtained under the first condition by 4 dB to 12 dB. In addition, the noise-reducing effect under the fourth condition was obtained over a wider frequency range compared to the noise-reducing effect under the third condition.

Next, an experiment was performed while the connection was provided at four positions by the conductive members 40a to 40d. This condition is hereinafter called a fifth condition. In this case, both the mounting area E and the electronic component 32 are surrounded by the imaginary lines ab, bc, cd, and ad. The noise-reducing effect obtained under the fifth condition was larger than that obtained under the first condition by 4 dB to 13 dB.

Next, an experiment was performed while the connection was provided at two positions by the conductive members 40b and 40d. This condition is hereinafter called a sixth condition. The imaginary line bd passes through both the electronic component 32 and the mounting area E. The noise-reducing effect obtained under the sixth condition was larger than that obtained under the first condition by 3 dB to 7 dB. In addition, the noise-reducing effect obtained under the sixth condition was larger than that obtained under the third condition in which the connection was provided at three positions by the conductive members 40a, 40b, and 40d. According to the third condition, a part of the electronic component 32 is not surrounded by the imaginary lines ab, bd, and ad. Therefore, in the case where the number of connecting sections is three or more, the conductive members are preferably positioned such that the electronic component 32 can be entirely surrounded by the imaginary lines.

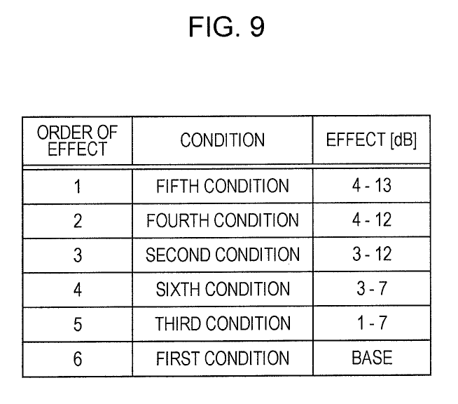

FIG. 9 is a table illustrating the result of the experiments performed under the above-described conditions. As is clear from FIG. 9, the maximum noise-reducing effect can be obtained under the fifth condition.

In the above-described embodiment, the mounting area E is interposed between the printed board 20 and the support plate 54 included in the keyboard 50. However, the mounting area E may also be interposed between a metal plate other than the keyboard 50 and the printed board 20. In addition, although a notebook personal computer is described as an example of an electronic apparatus, the electronic apparatus may also be other information technology equipment, such as a desktop personal computer and a printer.

All examples and conditional language recited herein are intended for pedagogical purposes to aid the reader in understanding the principles of the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiment(s) of the present invention(s) has(have) been described in detail, it should be understood that the various changes, substitutions, and alterations could be made hereto without departing from the spirit and scope of the invention.

1. An electronic apparatus, comprising:
a printed board having a mounting surface and a ground layer, a peripheral circuit of a memory, which is mounted in the electronic apparatus, being mounted on the mounting surface;
a metal plate disposed above the mounting surface; and
a plurality of conductive portions that electrically connect the ground layer and the metal plate to each other,
wherein the peripheral circuit is mounted between the conductive portions.

2. The electronic apparatus according to claim 1, wherein the printed board includes a signal layer on which wiring for the memory is formed, the signal layer being positioned between the ground layer and the mounting surface.

3. The electronic apparatus according to claim 1, wherein the conductive members are in the shape of a frame which surrounds the peripheral circuit.

4. The electronic apparatus according to claim 1, wherein a minimum distance between the conductive portions is about one-fourth of a wavelength of an electromagnetic wave at a predetermined frequency.

5. The electronic apparatus according to claim 1, wherein the metal plate supports an input key.
